(19) United States
(12) Patent Application Publication
(10) Pub. No.: US 2023/0375939 A1
(43) Pub. Date: Nov. 23, 2023

(54) METHOD FOR PRODUCING A MULTI-PART MIRROR OF A PROJECTION ILLUMINATION SYSTEM FOR MICROLITHOGRAPHY

(71) Applicant: Carl Zeiss SMT Gmbh, Oberkochen (DE)

(72) Inventors: Christoph Zaczek, Heubach (DE); Erik Loopstra, Huernheim (DE); Eric Eva, Aalen (DE)

(21) Appl. No.: 18/362,630

(22) Filed: Jul. 31, 2023

Related U.S. Application Data
(63) Continuation of application No. PCT/EP22/52162, filed on Jan. 31, 2022.

(30) Foreign Application Priority Data
Feb. 15, 2021 (DE) 102021201396.1

(51) Int. Cl. G03F 7/00; G02B 5/08

(52) U.S. Cl. CPC G03F 7/70166; G02B 5/0891

(57) ABSTRACT

A method for producing a mirror of a projection exposure apparatus for microlithography includes providing at least one material blank. The material blank comprises a material with a very low coefficient of thermal expansion and has fault zones within which at least one material parameter deviates from a specified value by more than a minimum deviation. A first mirror part having a first connecting surface is produced from the material blank. A second mirror part having a second connecting surface is produced from the material blank or a further material blank. The first and second mirror parts are permanently connected to one another in the region of the first and second connecting surfaces.

### CROSS-REFERENCE TO RELATED APPLICATIONS

The present application is a continuation of, and claims benefit under 35 USC 120 to, international application PCT/EP2022/052162, filed Jan. 31, 2022, which claims benefit under 35 USC 119 of German Application No 10 2021 201 396.1, filed Feb. 15, 2021. The entire disclosure of each these applications is incorporated by reference herein.

### FIELD

The disclosure relates to a method for producing a multipart mirror of a projection exposure apparatus for microlithography. The disclosure also relates to a multipart mirror of a projection exposure apparatus for microlithography, to an illumination optical unit, to a projection optical unit and to a projection exposure apparatus for microlithography.

### BACKGROUND

Projection exposure apparatuses for microlithography are used in particular in the production of semiconductors and generally have an illumination optical unit and a projection optical unit. The illumination optical unit generates from the light of a light source a desired light distribution for the illumination of a reticle, which is often also referred to as a mask. Light should be understood in this case in the general sense of electromagnetic radiation, which is to say there is no restriction to a specific wavelength. Accordingly, hereafter the terms “light” and “radiation” are used synonymously, which is to say a light source may also be referred to as a radiation source, a light distribution may also be referred to as a radiation distribution and so on. With the projection optical unit, the reticle is imaged onto a light-sensitive material, which is for example applied to a wafer or some other substrate, in particular of a semiconductor material. In this way, the light-sensitive material is exposed in a structured manner to a pattern predefined by the reticle. Since the reticle has tiny structural elements, which are intended to be transferred to the substrate with high precision, it is desirable for the illumination optical unit to generate a desired light distribution precisely and reproducibly and the imaging by the projection optical unit takes place precisely and reproducibly.

In addition to further optical elements, the illumination optical unit and the projection optical unit may have in the light path at least one mirror, which deflects the light in a predefined way by reflection at its optical surface. How the light deflection specifically takes place depends on the shape of the optical surface. The optical surface may for example be formed as a metallic layer or as a series of layers with alternating refractive indices.

It may be desirable to form the mirror from more than one part, for example if the mirror is intended to have cooling channels or if the mirror is intended to be larger than the material blanks available for the production of the mirror.

A multipart mirror with cooling channels is known from DE 102020208648.6, which is not a prior publication.

A multipart embodiment of the mirror may have a negative effect on the optical properties of the mirror, especially if the mirror parts do not have exactly the same material properties.

Should the mirror be a constituent part of the illumination optical unit, this may lead to a deviation from the specification of the light distribution generated by the illumination optical unit. Should the mirror be a constituent part of the projection optical unit, imaging aberrations may occur during the imaging using the projection optical unit.

With increasing miniaturization in semiconductor manufacturing, the illumination and the imaging of the reticle is carried out with ever increasing precision. This leads to ever more stringent demands being placed on the optical properties of the optical elements, for example mirrors, used in an illumination optical unit or projection optical unit.

### SUMMARY

The disclosure seeks to develop a multipart mirror of a projection exposure apparatus for microlithography so that the optical properties thereof satisfy very stringent demands. For example, the mirror can have good optical properties and be reliably usable even under thermal loads.

In a first variant of the method according to the disclosure for producing a mirror of a projection exposure apparatus for microlithography, at least one material blank is provided, the material blank comprising or consisting of a material with a very low coefficient of thermal expansion and having fault zones within which at least one material parameter deviates from a specified value by more than a minimum deviation. A first mirror part having a first connecting surface is produced from the material blank. A second mirror part having a second connecting surface is produced from the material blank or a further material blank. The first mirror part and the second mirror part are permanently connected to one another in the region of the first connecting surface of the first mirror part and the second connecting surface of the second mirror part. The volume region of the material blank from which the first mirror part is produced and/or the volume region of the material blank or of the further material blank from which the second mirror part is produced is determined on the basis of the spatial formation of the fault zones in the material blank or in the material blanks. In this case, the volume regions of the material blank or material blanks for the first mirror part and the second mirror part are chosen in such a way that the fault zones continue from the first mirror part into the second mirror part following the connection of the first mirror part to the second mirror part.

The method according to the disclosure can allow the production of a multipart mirror of a projection exposure apparatus for microlithography, the optical properties of which satisfy very stringent demands. By taking account of the spatial formation of the fault zones within the material blank, it is possible to produce a mirror which exhibits a very good thermal behavior and which has good optical properties even under thermal load.

The continuation of the fault zones from the first mirror part into the second mirror part can be defined in such a way that the fault zones continue from the first mirror part into the second mirror part without a lateral offset or with only a small lateral offset. In this case, a small lateral offset of the fault zones can be defined such that the lateral offset for at least 50%, optionally at least 80% of the fault zones is less than 50%, such as less than 30%, for example less than 10%, of the dimensions of the respective fault zone in the direction of the offset. In this case, the direction of the offset can be taken separately for each fault zone as the direction in which the lateral offset between the first mirror part and the second mirror part is greatest for the respective fault zone.

In particular, the volume region of the material blank for the second mirror part can be chosen so that it is displaced along the fault zones relative to the volume part of the material blank for the first mirror part. In this way, the properties accompanying a continuation of the fault zones from the first mirror part into the second mirror part, for example small mechanical stresses in the region of the connecting surfaces, can be used in a targeted manner.

By way of example, the specified value can be a mean value of the material parameter which is produced by averaging over the entire volume or a part of the volume of the respective material blank. This also applies to the further variant of the method according to the disclosure explained hereinbelow.

In a further variant of the method according to the disclosure for producing a mirror of a projection exposure apparatus for microlithography, a material blank is provided, the material blank comprising or consisting of a material with a very low coefficient of thermal expansion and having fault zones within which at least one material parameter deviates from a specified value by more than a minimum deviation. A first mirror part having a first connecting surface is produced from the material blank. Furthermore, a second mirror part having a second connecting surface is produced from the material blank. The first mirror part and the second mirror part are permanently connected to one another in the region of the first connecting surface of the first mirror part and the second connecting surface of the second mirror part. The first mirror part and the second mirror part are produced from volume regions of the material blank which are spaced apart from one another by the sum of a material addition for the production of the first mirror part and a material addition for the production of the second mirror part. In this case, the material additions for the production of the two mirror parts may each proportionally contain, in addition to the material addition for processing the respective mirror part, for example by grinding and polishing, a material addition for the separation of the mirror parts from the material blank, for example by sawing or cutting. Consequently, the individual material additions respectively correspond to the material ablation by the respective processing step, which is to say for example a cutting loss, a grinding loss, or a polishing loss. In particular, the distance should be kept as small as possible such that the desired material additions can only just still be observed.

This further variant of the method according to the disclosure also allows the production of a multipart mirror of a projection exposure apparatus for microlithography which has very good optical properties and a very good thermal behavior. This further variant can involve comparatively little outlay. Knowledge of the spatial formation of the fault zones is not mandatory. Nevertheless, this is helpful so as to be able to estimate the properties of the produced mirror.

A lateral offset of the fault zones possibly arising at the transition between the mirror parts can be reduced. This in turn may have a positive effect on the durability of the mirror and on its thermal properties.

Within the scope of the method according to the disclosure, at least one material blank in particular may be provided from fused silica, titanium-doped fused silica or a glass ceramic. These materials are available with very good qualities and have excellent suitability for the use in a projection exposure apparatus for microlithography. The material blank or the material blanks made of fused silica or titanium-doped fused silica can be produced in a direct deposition process or in a soot process, for example. High-quality material blanks with precisely defined specifications can be produced using these processes.

The first mirror part and the second mirror part can be produced either from the same material blank or from two separate material blanks. The production from one material blank allows for the material parameters to generally vary only very little and hence both mirror parts are made of virtually exactly of the same material. The use of two separate material blanks can offer more freedoms in relation to the arrangement of the fault zones in the mirror parts. In the case of two material blanks, they should have a similar spatial formation of the fault zones. By way of example, this can be implemented by producing the material blanks using the same manufacturing device in quick temporal succession and using the same process parameters. Similarly formed fault zones allow a continuous transition between the two mirror parts and reduce the risk of the connected mirror parts detaching from one another.

The material parameter can be a specification regarding the material composition, for example the titanium content or OH content, or a specification regarding a material property, for example the zero crossing temperature or the gradient of the coefficient of thermal expansion.

In an embodiment of the method according to the disclosure, the volume regions of the material blank for the first mirror part and the second mirror part which lead to the smallest image aberrations during the operation of the projection exposure apparatus can be simulated on the basis of the spatial formation of the fault zones. The simulation can be based on certain use scenarios for the projection exposure apparatus. In this way, it is possible to obtain particularly good optical properties and reduce the risk of the manufactured mirror not meeting the desired properties. Moreover, this can allow for optimal use of the available material blanks.

The first mirror part and the second mirror part can be separated from the material blank, at least in certain regions, along a curved separation surface. The curved separation surface can extend between the volume region for the first mirror part and the volume region for the second mirror part. In particular, the curved separation surface may extend between the portions of the material blank which are provided for the formation of the first connecting surface of the first mirror part and the second connecting surface of the second mirror part. Furthermore, the curvature of the separation surface may substantially correspond with the curvature of the first connecting surface of the first mirror part or the second connecting surface of the second mirror part. These measures allow for the material addition for the production of the first mirror part in the region of the first connecting surface and the material addition used for the production of the second mirror part in the region of the second connecting surface to be kept small. In turn, this allows the provision of the volume regions for the first mirror part and for the second mirror part at a very short distance from one another within the material blank. Consequently, there is a good chance of the fault zones in the mirror parts produced in this manner having a very similar formation at the location of the first connecting surface and at the location of the second connecting surface and not having a noticeable lateral offset from one another, which is to say the lateral offset can be reduced even further. The separation along the curved separation surface can be implemented via separative ball grinding.

The relative orientation with which the first mirror part and the second mirror part are connected to one another can be determined on the basis of the spatial formation of the fault zones in the material blank or in the material blanks. By way of example, the relative orientation during the connection can be chosen so that the fault zones continue from the first mirror part into the second mirror part without noticeable lateral offset. It is likewise also possible to choose the relative orientation during the connection so that the fault zones continue from the first mirror part into the second mirror part with a noticeable lateral offset. For example, it is possible to choose a maximum possible lateral offset. Both procedures have different effects on the formation of local stresses in the region of the connecting surfaces of the mirror parts and on the thermal behavior of the mirror, with the result that targeted influencing in this respect is possible. A large lateral offset may be desirable for example in the case of pupil-near mirrors of the projection exposure apparatus, which is to say in the case of mirrors arranged in the vicinity of a pupil plane or a plane of the projection exposure apparatus conjugate thereto. For example, a large lateral offset may be desirable in the case of periodically formed fault zones.

In particular, the first mirror part and the second mirror part can be produced from laterally offset volume regions of the material blank. In this case, the lateral offset of the volume regions may be specified on the basis of the spatial formation of the fault zones within the material blank. In this way, the profile of the fault zones for example can be reproduced by way of the offset of the volume regions and, as a result, it is possible to prevent the material loss during the processing of the mirror parts ultimately having as a consequence a lateral offset of the fault zones between the mirror parts in the completed mirror.

Likewise, it is also possible for the first mirror part and the second mirror part to be produced from volume regions of the material blank which are tilted relative to an outer surface or an axis of the material blank. In this case, the volume regions of the material blank may be tilted in relation to all outer surfaces of the material blank. In particular, the volume regions can be tilted in such a way that the fault zones in the material blank extend approximately parallel to the portion of the material blank provided for the formation of that outer surface of the second mirror part on which the optical surface is formed. What is achieved as a result is that only a few fault zones intersect this outer surface and, as a consequence of the slightly deviating material hardness thereof, promote the formation of a corrugated surface, which would have a negative effect on the optical surface, when processing the second mirror part.

The first mirror part and the second mirror part can be connected to one another in the same relative orientation as in the material blank. In this way, an offset of the fault zones between the first and the second mirror part, for example on account of a twisting of the mirror parts, can be avoided. At least one auxiliary frame may be used or at least one marking may be attached to the material blank in order to label the orientation in the material blank. As a result, a connection in the same relative orientation can be ensured using a relatively simple approach.

The volume regions of the material blank or material blanks for the first mirror part and the second mirror part can be chosen so that the manifestation of the fault zones at the location of the first connecting surface of the first mirror part and at the location of the second connecting surface of the second mirror part in each case is below a limit value. As a result, possible negative effects of the fault zones can be restricted in the region of the connecting surfaces, independently of the pose of the fault zones. In particular, the manifestation of the fault zones is below the limit value whenever the proportion of the area of the fault zones in the respective connecting surface is below a threshold value. In other words, the region of the respective connecting surface taken up by the fault zones overall divided by the entire area of the respective connecting surface is below the threshold value.

The threshold value may be defined as the arithmetic mean of the minimum value and the maximum value for the proportion of the area of the fault zones in the respective connecting surface when varying the arrangement of the volume regions for the first mirror part and second mirror part in the material blank or in the material blanks. In this case, it is also possible to separately determine a respective minimum value and a respective maximum value for the proportion of the area for the first mirror part and for the second mirror part, and to accordingly set a respective threshold value for the first connecting surface and for the second connecting surface.

Moreover, it is possible to demand that the threshold value is undershot by for example at least 30%, such as at least 60% of the interval between the minimum value for the proportion of the area of the fault zones and the threshold value.

A respective area can be chosen per material blank so that the areas have a similar spatial formation of the fault zones, and the first mirror part can be produced from a volume region within one of the areas and the second mirror part can be produced from a volume region within another area. For example, the volume regions for the first mirror part and the second mirror part can be arranged so that they immediately adjoin one another if the volume region for the second mirror part, while maintaining its pose relative to the fault zones, is transferred into the area containing the volume region for the first mirror part. An arrangement of the volume regions in the case of which the aforementioned transfer can lead to the first connecting surface and the second connecting surface being produced from directly adjacent portions of the volume regions is particularly advantageous. These measures can allow for the lateral offset of the fault zones between the mirror parts to be kept small despite the loss of material when separating out and processing the mirror parts.

The disclosure also relates to a mirror of a projection exposure apparatus for microlithography. A mirror according to the disclosure can have a first mirror part and a second mirror part which are produced from a material with a very low coefficient of thermal expansion. The first mirror part and the second mirror part are permanently connected to one another in the region of a first connecting surface of the first mirror part and a second connecting surface of the second mirror part. The first mirror part and the second mirror part have fault zones, within which at least one material parameter deviates from a specified value by more than a minimum deviation. The fault zones of the first mirror part can adjoin fault zones of the second mirror part with at least 50% of the overall area taken up by them at the location of the first connecting surface.

A mirror according to the disclosure can exhibit a very good thermal behavior and its optical properties meet very high demands, especially also under a thermal load. Possible issues arising due to a jump-like change of material parameters during the transition from the first to the second mirror part can be kept small. This is especially important for the mirrors of the projection exposure apparatus, which react particularly sensitively to such jump-like changes, for example near-field mirrors, which is to say for example mirrors which are arranged in the vicinity of an object plane or a plane of the projection exposure apparatus conjugate thereto.

By way of example, the specified value can be a mean value of the material parameter which is produced by averaging over the entire volume or a part of the volume of the respective mirror part.

For example, the fault zones of the first mirror part can adjoin fault zones of the second mirror part with at least 70%, such as at least 90% of the overall area taken up by them at the location of the first connecting surface.

The second mirror part may have an optical surface.

It is likewise also possible for the fault zones in the second mirror part to extend substantially parallel to the optical surface. For example, the surface of the second mirror part, on which the optical surface is formed, may have a maximum of 10, such as a maximum of 5, for example a maximum of 2 fault zones.

This can restrict unwanted corrugations of the optical surface, which can be traced back to a local variation in the surface hardness of the second mirror part.

The first mirror part and/or the second mirror part may contain titanium and/or OH. In particular, the first mirror part and/or the second mirror part may be produced from fused silica, titanium-doped fused silica, or a glass ceramic. In relation to the mass, the first mirror part and/or second mirror part may have an OH content of less than 400 ppm. In relation to the mass, it is likewise possible for the first mirror part and/or second mirror part to have an OH content of more than 600 ppm. The mirror may have cooling channels in the region of the first mirror part and/or in the region of the second mirror part.

The material parameter defining the fault zones can for example be the titanium content, the OH content, the zero crossing temperature, or the gradient of the coefficient of thermal expansion.

Averaged over the lateral region of the optical surface, the second mirror part may have a zero crossing temperature which deviates by −0.5 K to +3 K, optionally by −0.5 K to +1.5 K, from the zero crossing temperature of the first mirror part. For example, the second mirror part can have a higher zero crossing temperature, averaged thus, than the first mirror part. Since the second mirror part tends to have a higher temperature than the first mirror part during the operation of the projection exposure apparatus, a higher zero crossing temperature has a lower thermal expansion as a consequence. The second mirror part may have a more homogeneous distribution of the zero crossing temperature over the volume than the first mirror part. Since the second mirror part has the optical surface, the material properties of the second mirror part are more important for the optical properties of the mirror than the material properties of the first mirror part.

The first mirror part and the second mirror part may have a similar titanium content and/or a similar OH content in a first volume region, which extends into the first mirror part up to a distance of 10 mm from the first connecting surface, and in a second volume region, which extends into the second mirror part up to a distance of 10 mm from the second connecting surface. For example, the second mirror part may have a titanium dioxide content in the second volume region which deviates by less than 0.04% by mass, optionally by less than 0.02% by mass, for example by less than 0.01% by mass, from the titanium dioxide content in the first volume region. Furthermore, the second mirror part may have an OH content in the second volume region which deviates by less than 5%, such as by less than 2%, for example by less than 1% of the OH content in the first volume region, from this OH content in the first volume region. In the case of the OH content, the percentage specification with regards to the deviation is consequently related to the OH content as a relative value. The mean values in the respective volume region can be used as values for the titanium dioxide content and OH content. Should the second mirror part have a thickness of less than 10 mm, then the entire second mirror part can be used as a second volume region.

The fault zones can continue from the first mirror part into the second mirror part. For example, the fault zones can continue from the first mirror part into the second mirror part without a lateral offset or with only a small lateral offset. By way of example, the lateral offset for at least 50%, optionally at least 80% of the fault zones can be less than 50%, such as less than 30%, for example less than 10%, of the dimension of the respective fault zone in the direction of the offset. In this case, the direction of the offset can be taken separately for each fault zone as the direction in which the lateral offset between the first mirror part and the second mirror part is greatest for the respective fault zone.

Moreover the disclosure relates to a mirror of a microlithographic projection exposure apparatus, wherein the mirror has a first mirror part and a second mirror part which are produced from a material with a very low coefficient of thermal expansion, and the first mirror part and the second mirror part are permanently connected to one another in the region of a first connecting surface of the first mirror part and a second connecting surface of the second mirror part. The first mirror part has a first mean value of a zero crossing temperature in a first volume region extending up to a distance of 10 mm into the first mirror part from the first connecting surface. The second mirror part has a second mean value of the zero crossing temperature in a second volume region extending up to a distance of 10 mm into the second mirror part from the second connecting surface. The first mean value of the zero crossing temperature deviates by less than 1 K from the second mean value of the zero crossing temperature.

A mirror according to the disclosure is advantageous in that it exhibits a very good thermal behavior and its optical properties meet very high demands, especially also under a thermal load. For example the risk of mechanical stresses which could lead to a deformation of the optical surface forming when the temperature of the mirror changes is reduced as a result of the small difference in the mean values of the zero crossing temperature in the region of the connecting surfaces.

For example, the first mean value of the zero crossing temperature may deviate from the second mean value of the zero crossing temperature in particular by less than 0.5 K, particularly such as by less than 0.1 K.

Should the second mirror part have a thickness of less than 10 mm, then the entire second mirror part can be used as a second volume region.

Outside of the first volume region, the first mirror part may have a third mean value of the zero crossing temperature which deviates more significantly from the second mean value of the zero crossing temperature than the first mean value of the zero crossing temperature.

For example, the third mean value of the zero crossing temperature may deviate more from the second mean value of the zero crossing temperature than the first mean value of the zero crossing temperature by at least 0.1 K, such as by at least 1 K, for example by at least 3 K.

The disclosure also relates to an illumination optical unit having a mirror according to the disclosure.

Furthermore, the disclosure relates to a projection optical unit having a mirror according to the disclosure.

In addition, the disclosure relates to a projection exposure apparatus for microlithography having an illumination optical unit according to the disclosure and/or a projection optical unit according to the disclosure.

### BRIEF DESCRIPTION OF THE DRAWINGS

The disclosure is explained in more detail below on the basis of the exemplary embodiments that are represented in the drawing, in which:

FIG. 1 schematically shows an exemplary embodiment of a projection exposure apparatus for EUV projection lithography in a meridional section,

FIG. 2 shows a schematic illustration of an exemplary embodiment of a projection exposure apparatus for DUV projection lithography,

FIG. 3 shows a schematic sectional illustration of an exemplary embodiment of a mirror according to the disclosure,

FIG. 4 shows a schematic sectional illustration of a material blank for producing the mirror in accordance with a first configuration of the method according to the disclosure,

FIG. 5 shows a schematic sectional illustration of a material blank for producing the mirror in accordance with a further configuration of the method according to the disclosure,

FIG. 6 shows a schematic sectional illustration of a material blank for producing the mirror in accordance with a further configuration of the method according to the disclosure,

FIG. 7 shows a schematic sectional illustration of a material blank for producing the mirror in accordance with a further configuration of the method according to the disclosure, and

FIG. 8 shows a schematic sectional illustration of two material blanks for producing the mirror in accordance with a further configuration of the method according to the disclosure.

### EXEMPLARY EMBODIMENTS

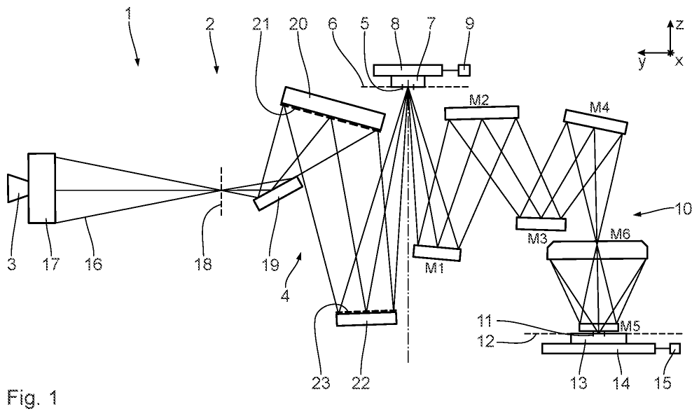

FIG. 1 schematically shows an exemplary embodiment of a projection exposure apparatus 1 for EUV projection lithography in a meridional section.

In the following text, certain component parts of a microlithographic projection exposure apparatus 1 are first described by way of example with reference to FIG. 1. The description of the basic structure of the projection exposure apparatus 1 and its components should not be construed as limiting here.

An embodiment of an illumination system 2 of the projection exposure apparatus 1 has, in addition to a light or radiation source 3, an illumination optical unit 4 for illuminating an object field 5 in an object plane 6. In an alternative embodiment, the radiation source 3 may also be provided as a separate module from the remaining illumination system. In this case, the illumination system does not comprise the radiation source 3.

A reticle 7 arranged in the object field 5 is exposed, the reticle also being referred to as a mask. The reticle 7 is held by a reticle holder 8. The reticle holder 8 is displaceable in particular in a scanning direction by way of a reticle displacement drive 9.

For purposes of explanation, a Cartesian xyz-coordinate system is shown in FIG. 1. The x-direction runs perpendicularly into the plane of the drawing. The y-direction runs horizontally, and the z-direction runs vertically. The scanning direction runs in the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 or of some other substrate arranged in the region of the image field 11 in the image plane 12. The wafer 13 is held by a wafer holder 14. The wafer holder 14 is displaceable, in particular in the y-direction, by way of a wafer displacement drive 15. The displacement, firstly, of the reticle 7 by way of the reticle displacement drive 9 and, secondly, of the wafer 13 by way of the wafer displacement drive 15 can be implemented so as to be mutually synchronized.

The radiation source 3 is an EUV radiation source. The radiation source 3 emits illumination radiation 16, which is also referred to below as used radiation or illumination light. In the exemplary embodiment shown, the illumination radiation 16 has a wavelength in the EUV range, in particular in the range between 5 nm and 30 nm. The radiation source 3 can be a plasma source, for example an LPP (laser produced plasma) source or a GDPP (gas discharge produced plasma) source. It may also be a synchrotron-based radiation source. Similarly, the radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), which is to say at angles of incidence of greater than 45°, or with normal incidence (NI), which is to say at angles of incidence of less than 45°. The collector 17 may be structured and/or coated, firstly for optimizing its reflectivity for the illumination radiation 16 and secondly for suppressing extraneous light.

Downstream of the collector 17, the illumination radiation 16 propagates through an intermediate focus in an intermediate focal plane 18. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond the pure deflection effect. As an alternative or in addition, the deflection mirror 19 may be in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. Only some of these first facets 21 are shown in FIG. 1 by way of example.

The first facets 21 may be embodied as macroscopic facets, in particular as rectangular facets or as facets with an arcuate edge contour or an edge contour of part of a circle. The first facets 21 can be embodied as plane facets or, alternatively, as convexly or concavely curved facets.

As is known for example from DE 10 2008 009 600 A1, the first facets 21 themselves can also each be composed of a multiplicity of individual mirrors, in particular a multiplicity of micromirrors. The first facet mirror 20 may in particular be in the form of a microelectromechanical system (MEMS system). For details, reference is made to DE 10 2008 009 600 A1.

The illumination radiation 16 travels horizontally, which is to say in the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or hexagonal boundary, or may alternatively be facets composed of micromirrors. In this regard, reference is likewise made to DE 10 2008 009 600 A1.

The second facets 23 can have plane or, alternatively, convexly or concavely curved reflection surfaces.

The illumination optical unit 4 consequently forms a double-faceted system. This fundamental principle is also referred to as a fly's eye condenser (fly's eye integrator).

It can be advantageous to arrange the second facet mirror 22 not exactly in a plane that is optically conjugate to a pupil plane of the projection optical unit 10. In particular, the second facet mirror 22 may be arranged so as to be tilted in relation to a pupil plane of the projection optical unit 10, as is described for example in DE 10 2017 220 586 A1.

The individual first facets 21 are imaged into the object field 5 using the second facet mirror 22. The second facet mirror 22 is the last beam-shaping mirror or indeed the last mirror for the illumination radiation 16 in the beam path upstream of the object field 5.

In a further embodiment of the illumination optical unit 4, not illustrated, a transfer optical unit can be arranged in the beam path between the second facet mirror 22 and the object field 5, said transfer optical unit contributing to the imaging of the first facets 21 into the object field 5, in particular. The transfer optical unit can comprise exactly one mirror or, alternatively, two or more mirrors, which are arranged in succession in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is regularly only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 in each case have a through-opening, through which, during the exposure of the wafer 13, the radiation contributing to the exposure passes on its way from the reticle 7 to the wafer 13. The projection optical unit has an image-side numerical aperture that is greater than 0.5 and may also be greater than 0.6 and may be for example 0.7 or 0.75.

The reflection surfaces of the mirrors Mi may be in the form of freeform surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a center of the object field 5 and a y-coordinate of the center of the image field 11. In the y-direction, said object-image offset can be approximately the same size as a z-distance between the object plane 6 and the image plane 12.

The projection optical unit 10 may in particular have an anamorphic form. In particular, it has different imaging scales βx, βy in the x- and y-directions. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, which is to say in a direction perpendicular to the scanning direction.

The projection optical unit 10 leads to a reduction in size of 8:1 in the y-direction, which is to say in the scanning direction.

Other imaging scales are likewise possible. Imaging scales with the same signs and the same absolute values in the x-direction and y-direction are also possible, for example with absolute values of 0.125 or 0.25.

The number of intermediate image planes in the x-direction and in the y-direction in the beam path between the object field 5 and the image field 11 can be the same or can differ depending on the embodiment of the projection optical unit 10. Examples of projection optical units 10 with different numbers of such intermediate images in the x-direction and y-direction are known from US 2018/0074303 A1.

In each case one of the second facets 23 is assigned to exactly one of the first facets 21 for respectively forming an illumination channel for illuminating the object field 5. This may in particular produce illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 is in particular as homogeneous as possible. It can have a uniformity error of less than 2%. The field uniformity can be achieved by overlaying different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, in particular the subset of the second facets 23, which guide light. This intensity distribution is also referred to as illumination setting or illumination pupil filling.

A likewise desirable pupil uniformity in the region of sections of an illumination pupil of the illumination optical unit 4 which are illuminated in a defined manner may be achieved by a redistribution of the illumination channels.

Further aspects and details of the illumination of the object field 5 and in particular of the entrance pupil of the projection optical unit 10 are described below.

The projection optical unit 10 may in particular have a homocentric entrance pupil. The latter can be accessible. It can also be inaccessible.

The entrance pupil of the projection optical unit 10 frequently cannot be exactly illuminated with the second facet mirror 22. When imaging the projection optical unit 10, which images the center of the second facet mirror 22 telecentrically onto the wafer 13, the aperture rays often do not intersect at a single point. However, it is possible to find a surface area in which the spacing of the aperture rays, determined in pairwise fashion, is minimal. This surface area represents the entrance pupil or an area in real space that is conjugate thereto. In particular, this surface area has a finite curvature.

The projection optical unit 10 might have different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted with respect to an arrangement plane defined by the deflection mirror 19.

The first facet mirror 20 is arranged so as to be tilted in relation to an arrangement plane defined by the second facet mirror 22.

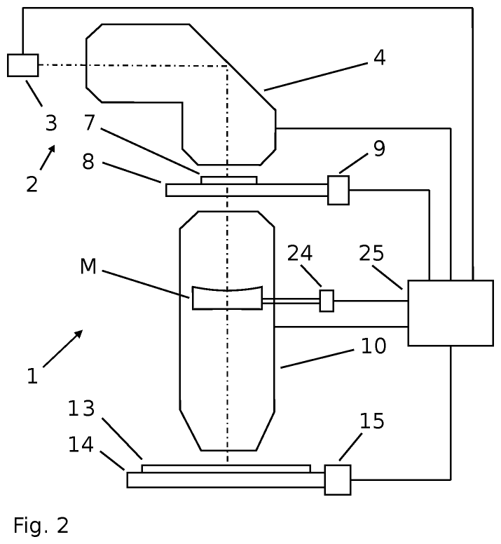

FIG. 2 shows an exemplary embodiment of a projection exposure apparatus 1 for DUV projection lithography in a schematic illustration. Here, DUV denotes “deep ultraviolet”. In particular, the projection exposure apparatus 1 may be designed for operation at a wavelength of 193 nm.

The projection exposure apparatus 1 has an illumination optical unit 4 and a projection optical unit 10. The internal structure of the illumination optical unit 4 and the internal structure of the projection optical unit 10, which may in each case comprise for example optical components, sensors, manipulators etc., are not shown in detail. In the case of the projection optical unit 10, a mirror M is indicated as representative of its optical components. The mirror M may be cooled with the aid of a cooling medium, which is provided by a cooling device 24. The cooling medium is a fluid, for example water. In addition or alternatively, the illumination optical unit 4 may have a cooled mirror M and an associated cooling device 24. The projection optical unit 10 and/or the illumination optical unit 4 may also have a plurality of cooled mirrors M and cooling devices 24. In the case of the illumination optical unit 4 and in the case of the projection optical unit 10, lenses and further mirrors—cooled or uncooled—may for example be present as further optical components.

By analogy, at least one cooling device 24, which may for example be connected to the mirror M3, may also be provided in the exemplary embodiment of the projection exposure apparatus 1 shown in FIG. 1.

The radiation used for the operation of the projection exposure apparatus 1 is generated by a radiation source 3. The radiation source 3 may be in particular an excimer laser, for example an argon fluoride laser, which generates illumination radiation 16 of the wavelength 193 nm.

Arranged between the illumination optical unit 2 and the projection optical unit 10 is a reticle holder 8, fixed on which is a reticle 7. The reticle holder 8 has a reticle displacement drive 9. Arranged downstream of the projection optical unit 10, seen in the direction of radiation, is a wafer holder 14, which carries a wafer 13 or some other substrate and has a wafer displacement drive 15.

Also shown furthermore in FIG. 2 is a control device 25, which is connected to the illumination optical unit 4, the projection optical unit 10, the cooling device 24, the radiation source 3, the reticle holder 8 or the reticle displacement drive 9 and the wafer holder 14 or the wafer displacement drive 15. By analogy, the projection exposure apparatus of FIG. 1 may likewise have a control device 25, which may be connected to corresponding components.

The projection exposure apparatus 1 serves the purpose of imaging the reticle 7 onto the wafer 13 with high precision. For this purpose, the reticle 7 is illuminated with the aid of the illumination optical unit 4 and the illuminated reticle 7 is imaged onto the wafer 13 with the aid of the projection optical unit 10. Specifically, the following procedure is adopted:

The illumination optical unit 4 transforms the illumination radiation 16 generated by the radiation source 3 in an exactly defined way via its optical components and guides it onto the reticle 7. Depending on the embodiment, the illumination optical unit 4 may be formed in such a way that it illuminates the entire reticle 7 or only a partial region of the reticle 7. The illumination optical unit 4 is capable of illuminating the reticle 7 in such a way that there are almost identical illumination conditions at each illuminated point of the reticle 7. In particular, the intensity and the angular distribution of the incident illumination radiation 16 are almost identical for each illuminated point of the reticle 7.

The illumination optical unit 4 is capable of illuminating the reticle 7 optionally with illumination radiation 16 of a multiplicity of different angular distributions. These angular distributions of the illumination radiation 16 are also referred to as illumination settings. The desired illumination setting is generally selected in dependence on the structure elements formed on the reticle 7. Used relatively often for example are dipole or quadrupole illumination settings, in the case of which the illumination radiation 16 is incident on each illuminated point of the reticle 7 from two different directions or from four different directions, respectively. Depending on the form of the illumination optical unit 4, the different illumination settings may be produced for example via different diffractive optical elements in combination with a zoom axicon optical unit or via mirror arrays, which have in each case a multiplicity of small mirrors that are arranged next to one another and are individually settable with respect to their angular position.

The reticle 7 may be formed for example as a glass plate, which is transparent to the illumination radiation 16 supplied by the illumination optical unit 4 and applied to which are opaque structures, for example in the form of a chromium coating.

The projection exposure apparatus 1 may be formed in such a way that the entire reticle 7 is illuminated at the same time by the illumination optical unit 4 and is imaged completely onto the wafer 13 by the projection optical unit 10 in a single exposure step.

Alternatively, the projection exposure apparatus 1 may also be formed in such a way that only a partial region of the reticle 7 is illuminated at the same time by the illumination optical unit 4 and the reticle displacement drive 9 is controlled by the control device 25 in such a way that, during the exposure of the wafer 13, the reticle 7 is moved in relation to the illumination optical unit 4 and, as a result, the illuminated partial region migrates over the reticle 7 as a whole. The wafer 13 is moved synchronously by suitably adapted control of the wafer displacement drive 15, in which the imaging properties of the projection optical unit 10 are also taken into account, and so the respectively illuminated partial region of the reticle 7 is imaged onto a partial region of the wafer 13 provided for it. This movement of the reticle 7 and of the wafer 13 is also referred to as scanning.

In order to be able to transfer the latent image produced by the exposure of the wafer 13 in both embodiments of the projection exposure apparatus 1 into a physical structure, a light-sensitive layer is applied to the wafer 13. The image of the reticle 7 is formed in this light-sensitive layer by exposure and a permanent structure can be produced from it on the wafer 13 with the aid of subsequent chemical processes.

The reticle 7 is generally imaged onto the wafer 13 not only once, but multiple times next to one another. For this purpose, after each imaging of the reticle 7 onto the wafer 13, the wafer holder 14 is displaced laterally in a way corresponding to the size of the image of the reticle 7 on the wafer 13. The imaging of the reticle 7 may be performed here in each case as a whole or sequentially by scanning. The chemical treatment of the wafer 13 is only started when the desired number of imaging representations of the reticle 7 on the wafer 13 have been carried out.

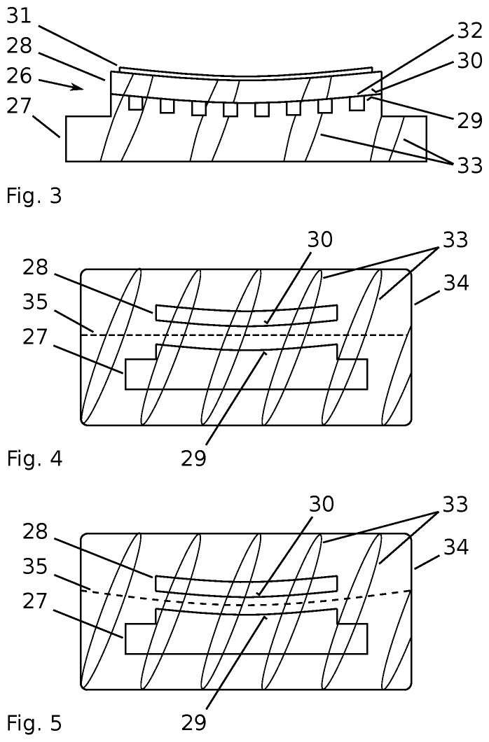

FIG. 3 shows a schematic sectional illustration of an exemplary embodiment of a mirror 26 according to the disclosure.

The mirror 26 can be used in one of the projection exposure apparatuses 1 shown in FIGS. 1 and 2 and has a lower part 27 and an upper part 28. The terms “lower part” and “upper part” have been chosen because the lower part 27 is generally formed much thicker than the upper part 28 and consequently carries the upper part 28, as it were. The terms do not, however, have anything to do with the orientation of the mirror 26 in relation to the direction of gravitational force in the mounted state of the mirror 26. During the operation of the projection exposure apparatus 1, the upper part 28 may be arranged above or below or alongside the lower part 27 with respect to the direction of gravitational force, or assume some other relative position with respect to it. The lower part 27 is also referred to as first mirror part. The upper part 28 is also referred to as second mirror part.

The lower part 27 and the upper part 28 are rigidly connected to one another in the region of a connecting surface 29 of the lower part 27 and a connecting surface 30 of the upper part 28. In the exemplary embodiment shown, the connecting surface 29 of the lower part 27 is formed in a concavely curved manner. The curvature may be formed spherically, aspherically or according to a freeform surface. The connecting surface 30 of the upper part 28 is curved in a way complementary to the connecting surface 29 of the lower part 27, and accordingly has a convex curvature, which may be formed spherically, aspherically or according to a freeform surface. Consequently, the connecting surface 30 of the upper part 28 and the connecting surface 29 of the lower part 27 can rest against one another in close contact. As an alternative to a curved formation, the connecting surface 29 of the lower part 27 and the connecting surface 30 of the upper part 28 may also be formed in a planar manner.

On the side that is facing away from its connecting surface 29 and is shown at the bottom in FIG. 3, the lower part 27 is formed in a planar manner. On the side that is facing away from its connecting surface 30 and is shown at the top in FIG. 3, the upper part 28 is formed in a concavely curved manner and has a reflective optical surface 31 with an identical curvature. The curvature may be formed spherically, aspherically or according to a freeform surface and in particular correspond to the curvature of the connecting surface 30 of the upper part 28 and extend parallel thereto. As an alternative to this, it is also possible that the optical surface 31 is formed in a planar manner. This is the case in particular if the connecting surface 29 of the lower part 27 and the connecting surface 30 of the upper part 28 are formed in a planar manner.

The optical surface 31 is embodied in particular as a coating applied to the upper part 28. The formation of the coating depends on the wavelength at which the optical surface 31 is intended to produce its reflective effect. In the case of a desired reflection in the DUV range, which is to say in the case of the mirror M in FIG. 2, the coating can be formed as an aluminum layer which is generally dielectrically reinforced and protected against oxidation by way of a coating. If, on the other hand, a reflection in the EUV range is intended, as in the case for example of the mirror M3, and so on, of FIG. 1, then the coating may be formed in particular from alternately successive layers of silicon and molybdenum and possibly one or more further layers of a different composition, which serve for example as protective layers.

The lower part 27 has a plurality of elongate cooling channels 32, which run parallel to one another and to the connecting surface 29 of the lower part 27 and extend laterally in the region of the optical surface 31 and possibly somewhat beyond it. Accordingly, the cooling channels 32 in the case of the exemplary embodiment shown are formed in a curved manner. The cooling channels 32 are formed to be open toward the connecting surface 29 of the lower part 27. The transverse dimensions of the cooling channels 32 may be about 0.2 to 10 mm, with the depth of the cooling channels 32, which is to say the dimension approximately perpendicular to the connecting surface 30 of the upper part 28, in the exemplary embodiment of FIG. 3 being approximately the same size as the width, which is to say the dimension approximately parallel to the connecting surface 30 of the upper part 28. However, it is likewise possible for the depth of the cooling channels 32 to be substantially larger than their width. For example, the depth of the cooling channels 32 may be more than twice the width of the cooling channels 32.

By way of example, using further channels not visible in FIG. 3, the cooling channels 32 may be connected to the cooling device 24 which is depicted in FIG. 2 and which can be used to generate a fluid flow through the cooling channels 32 and thus remove heat from the mirror 26. A heat influx into the mirror 26 can for example be implemented by the radiation which is reflected by the optical surface 31 during the operation of the projection exposure apparatus 1. Since the optical surface 31 does not completely reflect the incident radiation, part of the radiation is absorbed by the optical surface 31 and, depending on the formation of the optical surface 31, also absorbed by the upper part 28 and converted into heat. Since the optical surface 31 and the upper part 28 have a certain thermal conductivity, part of this heat is guided to the cooling channels 32 and can be taken up there by the fluid and transported away. In this way, the rise in temperature of the mirror 26 caused by the radiation can be limited and the deformation of the optical surface 31 caused by thermal expansion effects can be reduced in comparison with an uncooled mirror 26. As a consequence, the imaging aberrations caused by the deformation are also reduced.

To keep the negative effects of the temperature fluctuations which arise despite the cooling measures as low as possible, a material with a very low coefficient of thermal expansion is used to manufacture the lower part 27 and the upper part 28. Suitable materials are for example fused silica, titanium dioxide-doped fused silica or special glass ceramics.

By way of example, averaged over its volume, the material may have a zero crossing temperature, where the thermal expansion of the material is minimal and equal to zero in the ideal case, of between 22 and 25° C. The mean zero crossing temperature is adjusted here to match the expected temperature, taking into account the cooling of the mirror 26, during the operation of the projection exposure apparatus 1. Depending on the method for producing the material, the increase in the coefficient of thermal expansion at 22° C. can be less than approx. 1.35 to 1.8 ppb/K². The homogeneity of the zero crossing temperature is better than ±5 K in the lateral region of the optical surface 31, which is to say the zero crossing temperature has a spatially dependent fluctuation of less than ±5 K in this region. It is likewise possible to provide a significantly higher mean zero crossing temperature, especially if local heating of the mirrors is provided in addition to the cooling.

The lower part 27 and the upper part 28 may have a similar titanium content and/or a similar OH content in a first volume region, which extends into the lower part 27 up to a distance of 10 mm from the first connecting surface 29, and in a second volume region, which extends into the upper part 28 up to a distance of 10 mm from the second connecting surface 30. In particular, the upper part 28 may have a titanium dioxide content in the second volume region which deviates by less than 0.04% by mass, optionally by less than 0.02% by mass, such as by less than 0.01% by mass, from the titanium dioxide content in the first volume region. Furthermore, the upper part 28 may have an OH content in the second volume region which deviates by less than 5%, such as by less than 2%, for example by less than 1% of the OH content in the first volume region, from this OH content in the first volume region. In the case of the OH content, the percentage specification with regards to the deviation is related to the OH content as a relative value. The mean values in the respective volume region can be used as values for the titanium dioxide content and OH content. Should the upper part 28 have a thickness of less than 10 mm, then the entire upper part 28 can be used as a second volume region.

The lower part 27 may have a first mean value of the zero crossing temperature in the first volume region. The upper part 28 may have a second mean value of the zero crossing temperature in the second volume region. The first mean value of the zero crossing temperature may deviate from the second mean value of the zero crossing temperature by less than 1 K, in particular by less than 0.5 K, such as by less than 0.1 K. Should the upper part 28 have a thickness of less than 10 mm, then the entire upper part 28 can be used as a second volume region.

Outside of the first volume region, the lower part 27 may have a third mean value of the zero crossing temperature which deviates more significantly from the second mean value of the zero crossing temperature than the first mean value of the zero crossing temperature. In particular, the third mean value of the zero crossing temperature may deviate more from the second mean value of the zero crossing temperature than the first mean value of the zero crossing temperature by at least 0.1 K, such as by at least 1 K, for example by at least 3 K.

It is likewise possible for the upper part 28, averaged over the lateral region of the optical surface 31, to have a deviation from the zero crossing temperature of the lower part 27 of between −0.5 K and +3 K. This deviation may be up to +5 K in the case of mirrors 26 that are relatively close to the source or in the case of actively heated mirrors 26. The deviation can be between −0.5 K and +1.5 K. The asymmetry of the admissible deviation in relation to lower and higher temperatures is based on the upper part 28 generally having a higher temperature than the lower part 27 during the operation of the projection exposure apparatus 1 and the thermal expansion being smallest close to the zero crossing temperature.

The mirror 26 has fault zones 33 both in the region of the lower part 27 and in the region of the upper part 28, at least one material parameter deviating by more than a minimum deviation from a specified value within the said fault zones. By way of example, the specified value can be a mean value of the material parameter which is produced by averaging over the entire volume or a part of the volume of the lower part 27 and upper part 28, respectively. The material parameter can be a specification regarding the material composition, for example the titanium content or OH content, or a specification regarding a material property, for example the zero crossing temperature or the gradient of the coefficient of thermal expansion. The fault zones 33 can be manifested to different extents, which is to say have differently pronounced deviations from the specified value.

The fault zones 33 have a strip-shaped form in the exemplary embodiment of FIG. 3, which is to say they extend with approximately unchanging cross section into the plane of the drawing. The fault zones 33 extend approximately parallel to one another and are slightly tilted relative to the vertical in the illustration of FIG. 3 and accordingly do not extend perpendicular to the side of the lower part 27 facing away from the connecting surface 29. The illustrated exemplary embodiment is furthermore distinguished in that the fault zones 33 continue from the lower part 27 into the upper part 28 without a lateral offset. There may likewise also be a lateral offset of the fault zones 33 during the transition from the lower part 27 to the upper part 28. In this case, the lateral offset for at least 50%, optionally at least 80% of the fault zones 33 can be less than 50%, such as less than 30%, for example less than 10%, of the dimensions of the respective fault zone 33 in the direction of the offset. In this case, the direction of the offset can be taken separately for each fault zone 33 as the direction in which the lateral offset between the lower part 27 and the upper part 28 is greatest for the respective fault zone 33.

The fault zones 33 may also have a different spatial formation. However, as a rule, it is advantageous if the fault zones 33 of the lower part 27 adjoin fault zones 33 of the upper part 28 with at least 50% of the overall area taken up by them at the location of the connecting surface 29. Alternatively, there is also the option of providing only a small overlap of the fault zones 33 in the region of the connecting surface 29 of the lower part 27 and/or the connecting surface 30 of the upper part 28 and accordingly of providing a significant lateral offset during the transition from the lower part 27 to the upper part 28. In this way, it is possible, for example, to attempt to compensate the influence of the fault zones 33 up to a certain degree.

To produce the mirror 26, the lower part 27 and the upper part 28 are produced as separate parts and then connected to one another, for example by way of a thermal bonding process. The optical surface 31 is generally formed only after connecting the lower part 27 and the upper part 28 in order to achieve the highest possible precision, in particular with respect to its shape, and to avoid damage to the optical surface 31 during the connecting process.

A few aspects of the production of the lower part 27 and upper part 28, and the combination thereof to form the mirror 26, are explained hereinbelow.

FIG. 4 shows a schematic sectional illustration of a material blank 34 for producing the mirror 26 in accordance with a first configuration of the method according to the disclosure. The contours of the lower part 27 and upper part 28 are likewise depicted in FIG. 4.

For example, the material blank 34 may comprise a titanium-doped fused silica, in particular a fused silica to which titanium dioxide has been added. Likewise, the material blank 34 may also contain ternary compounds, which contain a further metal in addition to silicon and titanium. Moreover, dopings with fluorine are possible. Different batches of material blanks 34 made of titanium-doped fused silica may vary in respect of for example titanium content, OH content, zero crossing temperature, etc. Moreover, there may also be corresponding variations at different locations within the same material blank 34, and accordingly non-negligible deviations from a specified value in this respect. By way of example, the specified value can be a mean value of the respective material parameter which is produced by averaging over the entire volume or a part of the volume of the material blank 34. By way of example, fault zones 33, within which the deviation from the specified value exceeds a minimum value, may be formed in the material blank 34.

To restrict the negative effects of the batch variations, the lower part 27 and the upper part 28 of the mirror 26 may be separated from the same material blank 34. The negative effects of the fault zones 33 can be limited by virtue of the fault zones 33 being taken into account when producing the mirror 26 from the material blank 34.

Depending for example on the production method and the geometry of the material blanks 34, this leads to a number of procedures in respect of the separation of the lower part 27 and upper part 28 from the material blank 34 and in respect of the assembly of the mirror 26 from the lower part 27 and upper part 28, which are explained in detail hereinbelow.

The material blank 34 depicted in FIG. 4 was produced in a direct deposition process. In relation to its mass, the material blank 34 has an OH content of more than 600 ppm. The fault zones 33 arising due to local deviations in the concentration of titanium and OH from the specified values may be formed as a three-dimensional strip pattern made of a multiplicity of strips running parallel to one another, as already described in relation to FIG. 3, and are accompanied by corresponding deviations of the gradient of the coefficient of thermal expansion and of the zero crossing temperature from corresponding specified values. In a manner analogous to FIG. 3, the longitudinal extent of the strips in FIG. 4 runs approximately perpendicular to the plane of the drawing, with the result that FIG. 4 depicts a section through the strip-shaped fault zones 33 running transversely to the longitudinal extent thereof. Like in FIG. 3, the strip-shaped fault zones 33 are also tilted with respect to the vertical in FIG. 4 and accordingly extend neither parallel nor perpendicular to the outer surfaces of the material blank 34.

In the case of a material blank 34 embodied thus, one possible procedure includes separating the lower part 27 and the upper part 28 from the material blank 34 with the smallest possible distance between them, with the connecting surface 29 of the lower part 27 and the connecting surface 30 of the upper part 28 facing one another. A separation surface 35 possible in this respect is indicated in FIG. 4. The separation surface 35 has a planar form and extends in a straight line in the region of the depicted cutting plane. This allows the use of separation tools with a relatively simple design.

Following the separation, the lower part 27 and the upper part 28 are brought into the desired shape, for example by milling, grinding and polishing. Accordingly, when the lower part 27 and the upper part 28 are separated out, an additional material addition for the subsequent processing should be provided in each case, in addition to a material addition for the separation procedure. Thus, for the production of the lower part 27, a proportional material addition for the separation procedure and a material addition for the processing of the lower part 27 should be provided as a material addition in the region of the connecting surface 29. For the production of the upper part 28, a proportional material addition for the separation procedure and a material addition for the processing of the upper part 28 should be provided as a material addition in the region of the connecting surface 30. Accordingly, the smallest possible distance between the volume regions of the material blank 34 from which the lower part 27 and the upper part 28 are produced corresponds to the sum of the material addition for the production of the lower part 27 and the material addition for the production of the upper part 28 or, expressed differently, the sum of the material addition for the separation of the lower part 27 and the upper part 28, the material addition for the subsequent processing of the lower part 27, and the material addition for the subsequent processing of the upper part 28.

The connecting surface 29 of the lower part 27 may in particular be brought into a form that corresponds approximately to the intended form of the optical surface 31, which is formed at a later time on the upper part 28.

What separating out at the smallest possible distance achieves is that the fault zones 33 in the region of the connecting surface 29 of the lower part 27 and in the region of the connecting surface 30 of the upper part 28 have a very similar form. Moreover, the lateral offset of the fault zones 33 between the connecting surface 29 of the lower part 27 and the connecting surface 30 of the upper part 28, which is caused by the tilt of the fault zones 33 vis-à-vis the vertical in conjunction with the material ablation accompanying the processing of the lower part 27 and upper part 28, is comparatively small. Consequently, it is possible to connect the lower part 27 and the upper part 28 to one another in the region of the connecting surface 29 of the lower part 27 and the connecting surface 30 of the upper part 28 such that, in the mirror 26, the fault zones 33 continue virtually unchanged from the lower part 27 into the upper part 28.

In order to achieve this, the lower part 27 and the upper part 28 are connected to one another substantially in the correct pose, which is to say with approximately the same relative position and orientation as in the material blank 34. By way of example, the connection can be brought about by thermal bonding. In this case, the connecting surfaces 29, 30 either can be directly interconnected in the blank state, or additives can be applied to the connecting surfaces 29, 30. However, additives that remain permanently on the connecting surfaces 29, 30 are avoided where possible since these may have a different coefficient of thermal expansion. Optionally, the lower part 27 and the upper part 28 can be interconnected by optical contact bonding prior to bonding.

A mirror deviation in respect of the relative position in the material blank 34 arises from the fact that the lower part 27 and the upper part 28 are in contact with one another in the completed mirror 26 and are arranged at a distance from one another in the material blank 34 in order to enable a separation along a plane separation surface 35 and subsequent material-ablating surface processing. As mentioned previously, this positional deviation together with the tilt of the fault zones 33 depicted in FIG. 4 leads to a mirror lateral offset of the fault zones 33 during the transition from the lower part 27 into the upper part 28.

The relative orientation adopted by the lower part 27 and the upper part 28 relative to one another within the material blank 34 can be maintained very accurately when connecting the lower part 27 and the upper part 28. By way of example, this can be ensured by virtue of using auxiliary frames or forming one or more markings on the material blank 34. The markings can be formed within the region which is separated from the material blank 34 for the production of the lower part 27 and/or within the region which is separated from the material blank 34 for the production of the upper part 28. By way of example, the markings can be formed as drilled holes, notches or grooves.

The markings can also be used to position the lower part 27 and the upper part 28 with high precision relative to one another during the connection, which is to say maintain not only the angular coordinates but also the spatial coordinates. However, in respect of the reproduction of the relative positioning in the material blank 34, restrictions arise as a result of the lower part 27 and the upper part 28 on the one hand being interconnected in contact and hence without spacing in the region of their connecting surfaces 29, 30 and on the other hand material being ablated in the region of their connecting surfaces 29, 30 during the processing thereof, meaning that a spacing is consequently present in the material blank 34 between the connecting surfaces 29, 30. With the aid of the configuration of the method according to the disclosure described in more detail hereinafter, it is possible to reduce the material loss and accordingly the spacing used in the material blank 34 and the restrictions accompanying this.

Deviating from the illustration of FIG. 4, the material blank 34 may also be formed to be substantially larger than what is involved for the production of a lower part 27 and an upper part 28. In particular, the material blank 34 can be so large that a plurality of lower parts 27 and/or a plurality of upper parts 28 can be produced therefrom. Then, there accordingly a desire for more separation surfaces 35 for separating out the individual lower parts 27 and/or upper parts 28. Even in the case of a material blank 34 used to produce only one lower part 27 and one upper part 28, it is possible to provide further separation surfaces 35 for separating excess material, especially if the material blank 34 is significantly larger than what is involved for the production of a lower part 27 and an upper part 28.

FIG. 5 shows a schematic sectional illustration of a material blank 34 for producing the mirror 26 in accordance with a further configuration of the method according to the disclosure. In a manner analogous to FIG. 4, the lower part 27 and the upper part 28 are separated from the material blank 34 along the separation surface 35 and are subsequently brought into a desired shape by a number of processing steps in the case of the configuration depicted in FIG. 5. The remaining explanations in relation to FIG. 4 also apply analogously to FIG. 5. However, there is a difference in respect of the procedure when separating out the lower part 27 and upper part 28 from the material blank 34 and in respect of the formation of the separation surface 35.

In FIG. 5, the separation surface 35 has not a planar but curved form in the region between the connecting surface 29 of the lower part 27 and the connecting surface 30 of the upper part 28.

In particular, the separation surface 35 may have a spherical form in this region. The curvature of the separation surface 35 approximately corresponds to the curvature of the connecting surfaces 29, 30 of the lower part 27 and upper part 28. In this way, the material addition used for the processing, both for the connecting surface 29 of the lower part 27 and for the connecting surface 30 of the upper part 28, can already be obtained for a smaller distance between the lower part 27 and the upper part 28 in the material blank 34 than is the case in the configuration of FIG. 4. In other words, it is possible to reduce the material loss between the connecting surfaces 29, 30 and accordingly reduce the distance between the lower part 27 and the upper part 28 in the material blank 34 by way of separating the lower part 27 and the upper part 28 from the material blank 34 along the curved separation surface 35. Accordingly, there is also a reduction in the positional deviation vis-à-vis the situation in the material blank 34 when connecting the lower part 27 and the upper part 28. In the completed mirror 26, this yields a continuation of the fault zones 33 from the lower part 27 to the upper part 28 with an even smaller change than in the configuration according to FIG. 4. If the fault zones 33 are arranged in tilted fashion, this moreover results in a smaller lateral offset of the fault zones 33 during the transition from the lower part 27 to the upper part 28 than in the configuration according to FIG. 4.

The separation of the lower part 27 and the upper part 28 from the material blank 34 along the curved separation surface 35 can be implemented with the aid of a process which is also referred to as separative ball grinding. During this process, a rotating grinding tool, embodied as a curved rotational surface, is increasingly immersed in the material blank 34, which rotates about an axis that is vertical in FIG. 5, and finally severs the latter. The lower part 27 and upper part 28 separated from the material blank 34 in this way each have a curved surface in the region of the processing with the rotating grinding tool. Separative ball grinding is described in detail in DE 102 33 777 A1.

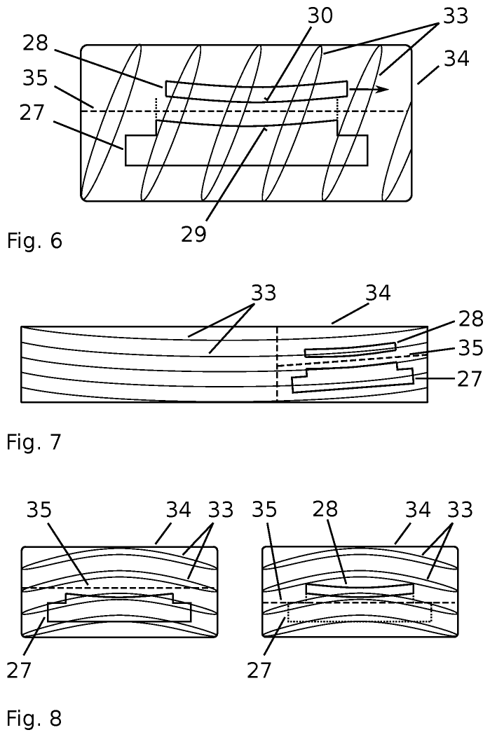

The two above-described configurations of the method according to the disclosure are primarily based on separating the lower part 27 and the upper part 28 from the material blank 34 in volume regions that are as close together as possible. A further possible procedure includes separating the lower part 27 and the upper part 28 from regions of the material blank 34 in which similar conditions are prevalent and in which, in particular, there is a similar spatial distribution of the fault zones 33. This is explained in detail hereinbelow on the basis of FIG. 6.

FIG. 6 shows a schematic sectional illustration of a material blank 34 for producing the mirror 26 in accordance with a further configuration of the method according to the disclosure. In a manner analogous to FIG. 4, the lower part 27 and the upper part 28 are separated from the material blank 34 along the separation surface 35, depicted using dashed lines, and are subsequently brought into a desired shape by a number of processing steps in the case of the configuration depicted in FIG. 6. The remaining explanations in relation to FIG. 4 also apply analogously to FIG. 6. However, there is a difference in respect of the procedure when separating out the lower part 27 and upper part 28 from the material blank 34 and/or the subsequent processing of the upper part 28.

In the configuration of FIG. 6, the contour of the upper part 28 is laterally offset relative to the contour of the lower part 27, with the result that the connecting surface 30 of the upper part 28 is not vertically flush with the connecting surface 29 of the lower part 27. To illustrate this, vertical auxiliary lines are plotted (using dotted lines) in FIG. 6. Moreover, the direction of the lateral offset is indicated by an arrow. The absolute value of the lateral offset of the upper part 28 relative to the lower part 27 approximately corresponds to the absolute value of the lateral offset of the fault zones 33, caused by the tilt of the fault zones 33, between the connecting surface 29 of the lower part 27 and the connecting surface 30 of the upper part 28.

This makes it possible to connect the upper part 28 to the lower part 27 without a lateral offset, or with only a small lateral offset, of the fault zones 33 despite the material additions used for the processing. To this end, the lower part 27 and the upper part 28 are separated from the material blank 34 along the separation surface 35 depicted in FIG. 6. Then, the lateral surface of the upper part 28, which is to say the surface delimiting the upper part 28 to the left and right in the illustration of FIG. 6, is milled and/or ground so that in the case of a connection of the lower part 27 and upper part 28 that is flush in relation to the connecting surfaces 29, 30 in the region of the connecting surfaces 29, 30 there is no offset or only a small offset of the fault zones 33 between the lower part 27 and the upper part 28. To this end, there is differently pronounced material ablation at different points of the lateral surface of the upper part 28 in order to obtain a lateral displacement of the fault zones 33 with respect to the outer contour of the upper part 28. Since the tilt of the fault zones 33 generally has a uniaxial form, the optimal lateral displacement of the fault zones 33 can be determined from the angle of this tilt and the sum of the material ablations on the connecting surface 29 and the connecting surface 30, which corresponds to the distance between the connecting surfaces 29, 30 in the material blank 34. If there is noticeable material loss when separating the lower part 27 and upper part 28 from the material blank 34 along the separation surface 35, then this material loss can be added, respectively proportionally, to the material ablation on the connecting surface 29 and the material ablation on the connecting surface 30, in order to slightly increase further the accuracy when determining the lateral displacement.

Alternatively, there is also the possibility of determining a lateral distribution of the fault zones 33 in the region of the connecting surfaces 29, 30 and determining the optimal lateral displacement by autocorrelation.

Likewise, the spatial formation of the fault zones 33 in the material blank 34 can be used to simulate the absolute value and the direction of the lateral displacement which lead to the smallest image aberrations during the operation of the projection exposure apparatus 1 under given operating conditions, and the upper part 28 can be processed accordingly. However, the displacement determined in this way does not necessarily lead to the smallest lateral offset of the fault zones 33 between the connecting surfaces 29, 30. A twist of the upper part 28 relative to the lower part 27 about an axis that is vertical in the illustration of FIG. 6 can be additionally used as a further variable in the simulation. Optionally, there also is the possibility of including not only the image aberrations in the determination of a suitable lateral displacement but also the local stresses which arise from the lateral offset of the fault zones 33 in the region of the connecting surfaces 29, 30, as these may have a negative effect on the durability of the connection between the lower part 27 and the upper part 28.

After the lateral surface of the upper part 28 has been processed, the further processing of the lower part 27 and upper part 28, and the connecting of the lower part 27 and the upper part 28, can be implemented in a manner analogous to the configurations of the method according to the disclosure already described above.

The lateral offset of the fault zones 33 can also be at least partly compensated by milling or grinding the lateral surface of the upper part 28 in the configuration depicted in FIG. 5, in which the lower part 27 and the upper part 28 are separated from the material blank 34 by separative ball grinding.

In addition or as an alternative to the fault zones 33 described up until now, the material blank 34 may have further fault zones 33, which are to be considered when separating the lower part 27 and the upper part 28 from the material blank 34. This will be explained on the basis of FIG. 7.

FIG. 7 shows a schematic sectional illustration of a material blank 34 for producing the mirror 26 in accordance with a further configuration of the method according to the disclosure. The material blank 34 was produced in a direct deposition process, in a manner analogous to the configuration depicted in FIG. 4. As a result of the layer-by-layer deposition of the material during the production process, there may be a periodic variation in the titanium content and OH content in a direction extending vertically in FIG. 7. As a result, layer-like fault zones 33 arise, with approx. 2 to 30 layers per mm. These fault zones 33 may arise in addition to the fault zones 33 depicted in FIG. 4. The following explanations are focused on the layer-like fault zones 33.

For reasons of clarity, only a few fault zones 33 are depicted in FIG. 7. It is evident from FIG. 7 that the fault zones 33 are not formed flat but are formed as curved layers. If the lower part 27 and the upper part 28 were separated from the material blank 34 in a manner parallel to a horizontal plane, then many fault zones 33 would intersect the region of the upper part 28 on which the optical surface 31 is formed. Since this region is firstly processed by grinding and polishing and since the fault zones 33 secondly have a slightly deviating material composition and hence also a deviating hardness, a distribution of unevenness corresponding to the layer pattern would be prepared in this region as a result of the ablation rate varying with hardness.

To avoid this, the lower part 27 and the upper part 28 can be produced from volume regions of the material blank 34 which have an orientation adapted to the formation of the fault zones 33, which is to say the contours of the lower part 27 and upper part 28 plotted in FIG. 7 are tilted relative to the outer surfaces or to an axis of the material blank 34. Accordingly, the separation of the lower part 27 and upper part 28 from the material blank 34 can also be implemented along a separation surface 35 that is tilted in the same way. As depicted in FIG. 7, this may for example be achieved by virtue of the separation surface 35 being tilted vis-à-vis the horizontal in a manner dependent on the local profile of the fault zones 33, with the result that the separation surface 35 runs approximately parallel to the fault zones 33. Alternatively, the profile of the fault zones 33 could be considered only when separating the upper part 28 from the material blank 34, by virtue of having a wedge-shaped cutting gap between the lower part 27 and the upper part 28. In the illustration of FIG. 7, this would mean that the orientation of the upper part 28 would remain unchanged while the lower part 27 would however be oriented horizontally. In both cases, the upper part 28 is further processed so that a surface of the upper part 28 on which the optical surface 31 is subsequently formed runs approximately parallel to the fault zones 33 so that as few fault zones 33 as possible intersect this surface. In particular, the surface of the upper part 28, on which the optical surface 33 is formed, may have a maximum of 10, such as a maximum of 5, for example a maximum of 2 fault zones 33. Otherwise, the processing of the lower part 27 and the upper part 28 can be implemented in a manner analogous to what has already been described above.

The lower part 27 and the upper part 28 may also be separated from a material blank 34 which was produced not by direct deposition but in another way. By way of example, the material blank 34 can be produced in a soot process, in which a cylindrically formed rod is rotated above an array of burners and material from the gaseous phase is continuously deposited on the cylinder. Fault zones 33 may form as a result of the slightly different deposition rates of the material in the region of the individual burners. The fault zones 33 may each extend over the entire cross section of the cylinder and run perpendicular to the cylinder axis, with a plurality of fault zones 33 following one another along the cylinder axis. The cylinder produced in this way can be reshaped into the material blank 34 by virtue of allowing the cylinder, heated until soft, to flow into a mold. Two material blanks 34 produced in this manner are depicted in FIG. 8.

FIG. 8 shows a schematic sectional illustration of two material blanks 34 for producing the mirror 26 in accordance with a further configuration of the method according to the disclosure. In relation to the mass, the OH concentration of the material blanks 34 is 400 ppm maximum. The material blanks 34 were each produced by a soot process and reshaped by flowing into a mold. As a result of the reshaping process, curved fault zones 33 emerge from the plane fault zones 33 oriented perpendicular to the cylinder axis, with the result that the material blanks 34 each have a plurality of successive curved fault zones 33.

By way of example, if the lower part 27 and the upper part 28 were separated out along the same separation surface 35 from the material blank 34 depicted to the left in FIG. 8, then there would be gaps in the curved fault zones 33 when the lower part 27 and the upper part 28 are assembled to form the mirror 26 following the processing, the gaps arising on account of the material loss due to this subsequent processing of the lower part 27 and the upper part 28. Such gaps can be avoided or at least reduced by way of different measures.

One measure includes separating the lower part 27 and the upper part 28 from different material blanks 34 which have a very similar embodiment in respect of the spatial distribution of the fault zones 33. In particular, a similar form of the fault zones 33 can be achieved by virtue of the same manufacturing device being used to manufacture the material blanks 34 and the material blanks 34 being produced in quick temporal succession using the same process parameters. The two material blanks 34 depicted in FIG. 8 are similarly embodied material blanks 34 which were produced in this way. Accordingly, the two material blanks 34 have a very similar or identical formation of the fault zones 33, with the material blank 34 depicted to the left in FIG. 8 serving the production of the lower part 27 and the material blank 34 depicted to the right in FIG. 8 serving the production of the upper part 28. Specifically, the following procedure is adopted:

The lower part 27 is separated along the separation surface 35 from the material blank 34 depicted to the left in FIG. 8. Then, the lower part 27 is processed in the manner already described above until it has the contour depicted to the left in FIG. 8.

In the material blank 34 depicted to the right in FIG. 8, the contour of the lower part 27 is plotted using a dotted line at a position which, in relation to the relative arrangement with respect to the fault zones 33, is equivalent to the position of the contour of the lower part 27 in the material blank 34 depicted to the left in FIG. 8. The orientation of the indicated contour of the lower part 27 in the case of the material blank 34 depicted to the right also corresponds to the orientation of the contour of the lower part 27 in the case of the material blank 34 depicted to the left. The contour of the upper part 28 is likewise plotted in the material blank 34 depicted to the right, and it directly adjoins the contour of the lower part 27 so that the connecting surface 29 of the lower part 27 and the connecting surface 30 of the upper part 28 immediately adjoin one another. However, the lower part 27 is not separated from the material blank 34 depicted to the right. Instead, only the upper part 28 is separated from the material blank 34 depicted to the right, with the separation surface 35 being offset toward the lower part 27 in comparison with the material blank 34 depicted to the left. The offset between the separation surfaces 35 for separating out the lower part 27 and for separating out the upper part 28 corresponds to the sum of the material additions for the lower part 27 and upper part 28 in the region of the connecting surfaces 29, 30. Like the lower part 27, the upper part 28 is also processed in the manner already described above post separation.

Then, the lower part 27 and the upper part 28 are assembled to form the mirror 26. The mirror 26 has no or only mirror gaps in the fault zones 33 in the region of the connecting surfaces 29, 30. This is based on the offset separation of the lower part 27 and upper part 28 from two similar material blanks 34 allowing the material loss occurring during the separation and processing to be dispensed with and hence this ultimately leads to the same result as if the lower part 27 and the upper part 28 were produced without material loss from immediately adjacent volume regions of the same material blank 34. In other words: If the volume region for the lower part 27, illustrated in FIG. 8 by the contour of the lower part 27, is transferred from the material blank 34 depicted to the left to the material blank 34 with a similar embodiment, depicted to the right, while maintaining its pose relative to the fault zones 33, then this volume region directly adjoins the volume region for the upper part 28, which is illustrated by the contour of the upper part 28. This has as a consequence that the connecting surface 29 of the fully processed lower part 27 and the connecting surface 30 of the fully processed upper part 28 are arranged in identical fashion relative to the spatial distribution of the fault zones 33. Consequently, the fault zones 33 continue seamlessly in the completed mirror 26 through the transition from the lower part 27 into the upper part 28 and there are no jumps between the connecting surface 29 of the lower part 27 and the connecting surface 30 of the upper part 28 in respect of the material parameter on which the fault zones 33 are based.

The size of the gaps in the fault zones 33 which arises when joining the lower part 27 and the upper part 28 therefore depends on the volume region of the material blank 34 depicted to the left in FIG. 8 from which the lower part 27 was produced and on the volume region of the material blank 34 depicted to the right in FIG. 8 from which the upper part 28 was produced.

The procedure described on the basis of FIG. 8 can also be applied in the case of a single material blank 34 should the latter have sufficiently large spatial dimensions.

A further measure includes reducing the material loss when separating out and processing the lower part 27 and upper part 28, to such an extent that comparatively small gaps arise. To this end, the lower part 27 and upper part 28 can be separated from the material blank 34 along a curved separation surface 35, for example by way of the already mentioned separative ball grinding. To keep the material loss as small as possible, the curvature of the separation surface 35 can be adapted to the curvature of the connecting surfaces 29, 30.

Although the separation along a curved separation surface 35 is accompanied by an improvement in relation to the separation along a planar separation surface 35, gaps in the fault zones 33 not present in the material blank 34 nevertheless arise in the region of the connecting surfaces 29, 30 when assembling the lower part 27 and upper part 28 to form the mirror 26.

As a further measure, it is also possible to characterize the material blanks 34 and respectively place the separation surfaces 35 for separating out the lower part 27 and upper part 28 in a region of the material blank 34 without noticeable fault zones 33. This measure is also applicable in the case of a single material blank 34 if the latter has a sufficient size. Moreover, this procedure can also be used in differently formed fault zones 33 and/or in differently produced material blanks 34. In particular, the volume regions of the material blank 34 or material blanks 34 for the lower part 27 and the upper part 28 can be chosen so that the manifestation of the fault zones 33 at the location of the first connecting surface 29 of the lower part 27 and at the location of the second connecting surface 30 of the upper part 28 in each case is below a limit value. In particular, the manifestation of the fault zones 33 is below the limit value whenever the proportion of the area of the fault zones 33 in the connecting surface 29 or in the connecting surface 30 is below a threshold value. The threshold value may be defined as the arithmetic mean of the minimum value and the maximum value for the proportion of the area of the fault zones 33 in the connecting surface 29 or in the connecting surface 30 when varying the arrangement of the volume regions for the lower part 27 and upper part 28 in the material blank 34 or in the material blanks 34. In this case, it is also possible to separately determine a respective minimum value and a respective maximum value for the proportion of the area for the lower part 27 and for the upper part 28, and to accordingly set a respective threshold value for the connecting surface 29 and for the connecting surface 30. Moreover, it is possible to demand that the threshold value is undershot by for example at least 30%, in particular at least 60% of the interval between the minimum value for the proportion of the area of the fault zones 33 and the threshold value.

Attempts can be made to homogenize the respective material blank 34 as a further measure. The options and procedures in this respect depend on the material and on the production process.

In all of the described configurations of the method according to the disclosure, it is also possible to deliberately deviate from the original profile of the fault zones 33 when connecting the lower part 27 and upper part 28, as an alternative to maintaining the profile of the fault zones 33 of the material blank 34. By way of example, the lower part 27 and the upper part 28 could be positioned and oriented relative to one another in such a way during the connection that there is a lateral offset of the fault zones 33 that is as large as possible at the transition from the lower part 27 to the upper part 28. As a result, the fault zones 33 in the region of the connecting surface 29 of the lower part 27 and the connecting surface 30 of the upper part 28 can in a certain sense be arranged with opposite phases to one another and the deviations of the material composition or the material properties accompanying the fault zones 33 can be partly compensated for in the region of the connecting surfaces 29, 30.

As an alternative to the use of an upper part 28 separated from a material blank 34, it is also possible for the upper part 28 to be produced by flowing out on molten metal (float glass), by pouring over a long break-away edge, by pressing and sintering of glass soot or indirectly by way of a gray body. Using these methods, it is possible to produce a slab which is a few millimeters thick and which has a good homogeneity.

### REFERENCE SIGNS

1 Projection exposure apparatus
2 Illumination system
3 Radiation source
4 Illumination optical unit
Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
24 Cooling device
25 Control device
26 Mirror
27 Lower part
28 Upper part
29 Connecting surface
30 Connecting surface
31 Optical surface
32 Cooling channel
33 Fault zone
34 Material blank
35 Separation surface
M Mirror
M1 Mirror
M2 Mirror
M3 Mirror
M4 Mirror
M5 Mirror
M6 Mirror

1. A mirror, comprising:
a first mirror part; and
a second mirror part,
wherein:
the first and second mirror parts comprises a material with a very low coefficient of thermal expansion;
the and second first mirror parts are permanently connected to one another in a region of a first connecting surface of the first mirror part and a second connecting surface of the second mirror part;
the first mirror part has a first mean value of a zero crossing temperature in a first volume region extending up to a distance of 10 mm into the first mirror part from the first connecting surface;
the second mirror part has a second mean value of the zero crossing temperature in a second volume region extending up to a distance of 10 mm into the second mirror part from the second connecting surface;
the first mean value of the zero crossing temperature is within 1 Kelvin from the second mean value of the zero crossing temperature.

2. The mirror claim 1, wherein the blank comprises a material selected from the group consisting of a fused silica, a titanium-doped fused silica, and a glass ceramic.

3. A unit, comprising:
a mirror according to claim 1, wherein the unit is an illumination optical unit.

4. A unit, comprising:
a mirror according to claim 1,
wherein the unit is a microlithgraphic projection optical unit.

5. An apparatus, comprising:
an illumination optical unit; and
a projection optical unit,
wherein the apparatus is a microlithographic projection exposure apparatus, and a member selected from the group consisting of the illumination optical unit and the projection optical unit comprises a mirror according to claim 1.

6. A mirror, comprising:
a first mirror part; and
a second mirror part,
wherein:
the first and second mirror parts comprise a material with a very low coefficient of thermal expansion;
the first and second mirror part are permanently connected to one another in the region of a first connecting surface of the first mirror part and a second connecting surface of the second mirror part;
the first and second mirror parts comprise fault zones within which at least one material parameter deviates from a specified value by more than a minimum deviation;
the fault zones of the first mirror part adjoin fault zones of the second mirror part with at least 50% of the overall area taken up by them at the location of the first connecting surface.

7. The mirror of claim 6, wherein the fault zones continue from the first mirror part into the second mirror part.

8. The mirror of claim 6, wherein the blank comprises a material selected from the group consisting of a fused silica, a titanium-doped fused silica, and a glass ceramic.

9. A unit, comprising:
a mirror according to claim 6, wherein the unit is an illumination optical unit.

10. A unit, comprising:
a mirror according to claim 6,
wherein the unit is a microlithgraphic projection optical unit.

11. An apparatus, comprising:
an illumination optical unit; and
a projection optical unit,
wherein the apparatus is a microlithographic projection exposure apparatus, and a member selected from the group consisting of the illumination optical unit and the projection optical unit comprises a mirror according to claim 6.

12. A method for producing a mirror, the method comprising:
producing a first mirror part from a first material blank, the first material blank comprising a material with a very low coefficient of thermal expansion and having fault zones with which a material parameter deviates from a specified value by more than a minimum deviation, the first mirror part having a first connecting surface;
producing a second mirror part from a second material blank, the second mirror part having a second connecting surface;
permanently connecting the first and second mirror parts to one another in a region of the first connecting surface of the first mirror part and the second connecting surface of the second mirror part; and
determining, based on a spatial formation of the fault zones in the first and second material blanks, at least one volume region of at least one member selected from the group consisting of the first material blank and the second material blank,
wherein the at least one volume region is chosen so that the fault zones continue from the first mirror part into the second mirror part following the connection of the first mirror part to the second mirror part.

13. The method of claim 12, wherein each of the first and second blanks comprises a material selected from the group consisting of a fused silica, a titanium-doped fused silica, and a glass ceramic.

14. The method of claim 12, wherein the first and second mirror parts are separated from the first and second material blanks, at least in certain regions, along a curved separation surface.

15. The method of claim 12, wherein a relative orientation with which the first and second mirror parts are connected to one another is determined based on the spatial formation of the fault zones in the first and second material blanks.

16. The method of claim 12, wherein the first and second mirror parts are produced from laterally offset volume regions of the first and second material blanks.

17. The method of claim 12, wherein the first and second mirror parts are produced from volume regions of the first and second material blanks which are tilted relative to an outer surface or an axis of the first and second material blanks.

18. The method of claim 12, wherein the first and second mirror parts are connected to one another in the same relative orientation as in the first and second material blanks.

19. The method of claim 12, wherein the volume regions of the first and second material are chosen so that the fault zones at the location of the first and sec and connecting surfaces are in each case is below a limit value.

20. (canceled)

21. A method for producing a mirror, the mirror comprising:
producing a first mirror part having a first connecting surface from a material blank, the material blank comprising a material with a very low coefficient of thermal expansion and having fault zones within which at least one material parameter deviates from a specified value by more than a minimum deviation;
producing aa second mirror part having a second connecting surface from the material blank;
permanently connecting the first and second mirror parts to one another in a region of the first and second connecting surfaces;
producing the first and second mirror parts from volume regions of the material blank which are spaced apart from one another by a sum of a material addition for the production of the first mirror part and a material addition for the production of the second mirror part.

22.-28. (canceled)
